(19) United States
(12) Patent Application Publication
(10) Pub. No.: US 2024/0055408 A1
(43) Pub. Date: Feb. 15, 2024

(54) SEMICONDUCTOR PACKAGE STRUCTURE AND METHOD FOR PREPARING SEMICONDUCTOR PACKAGE STRUCTURE

(71) Applicant: CHANGXIN MEMORY TECHNOLOGIES, INC., Hefei City (CN)

(72) Inventors: Kaimin LV, Hefei City (CN); LING-YI CHUANG, Hefei City (CN)

(73) Assignee: CHANGXIN MEMORY TECHNOLOGIES, INC., Hefei City (CN)

(21) Appl. No.: 18/451,060

(22) Filed: Aug. 16, 2023

Related U.S. Application Data
(63) Continuation of application No. PCT/CN2022/123768, filed on Oct. 8, 2022.

(30) Foreign Application Priority Data
Aug. 10, 2022 (CN) 202210959176.4

(51) Int. Cl. H01L 25/065; H01L 23/00; H10B 80/00; H01L 25/00

(52) U.S. Cl. CPC H01L 25/0657; H01L 24/16; H01L 24/32; H01L 24/33; H01L 24/73; H10B 80/00; H01L 25/50; H01L 2224/16146; H01L 2224/16225; H01L 2224/32145; H01L 2224/32225; H01L 2224/33517; H01L 2224/73204; H01L 2224/73253; H01L 2225/06517; H01L 2225/0652; H01L 2225/06513; H01L 2225/06541; H01L 2924/1436; H01L 2924/1811

(57) ABSTRACT

A semiconductor package structure includes: a first substrate; a first semiconductor die connected to the first substrate; a second semiconductor die stack structure located on the first semiconductor die, the second semiconductor die stack structure includes a plurality of second semiconductor dies sequentially stacked onto one another in a first direction, a plurality of second conductive bumps being formed on a side of the second semiconductor die stack structure in the first direction, in which the first direction is a direction parallel to a plane where the first substrate is located; and a second substrate, a signal line in the second substrate being connected to the plurality of second conductive bumps, the second substrate being connected to the first substrate in a direction perpendicular to the plane where the first substrate is located.

### CROSS-REFERENCE TO RELATED APPLICATIONS

This is a continuation of International Patent Application No. PCT/CN2022/123768 filed on Oct. 8, 2022, which claims priority to Chinese Patent Application No. 202210959176.4 filed on Aug. 10, 2022. The disclosures of the above-referenced applications are hereby incorporated by reference in their entirety.

### BACKGROUND

A high bandwidth memory (HBM) is a high-performance DRAM based on a 3D stack process. Compared with traditional memories, the HBM has a higher bandwidth, a greater number of I/O, lower power consumption and a smaller dimension, and the HBM may be applied to fields such as high-performance computing, supercomputers, large-scale data centers, artificial intelligence/deep learning and cloud computing.

The HBM technology is mainly developed based on the demand for a computing scale of a processor. In the early days, peoples did not have high requirements for the data processing of a computer, that is to say, the processor has fewer layers of architecture model, a smaller computing scale and lower computing power. Later, with the development of technologies such as AI, the requirements for the processor is getting higher and higher, and the demands for the computing power increase correspondingly with the deepening of a model, which leads to a bottleneck of the bandwidth, i.e., a bottleneck of I/O. At this point, the bottleneck of the bandwidth is solved by increasing an on-die cache and optimizing a scheduling model to increase a data reuse rate. However, in the later period, with the popularization of the technologies such as AI, the number of users is increased, and the AI processing in a cloud demands multiple users, high throughput, a low latency and a high density deployment, and a sharp increase in the number of computing units makes the bottleneck of I/O more serious. At this point, the emergence of an on-die HBM makes it possible for the AI/deep learning to be completely put on a die, and not only improves an integration level of the HBM, but also makes the bandwidth no longer limited by the number of interconnected pins of the die, which solves the bottlenecks of the bandwidth and the computing power to a certain extent.

However, with the increasing requirements of the integration level of the HBM, the number of stacked dies is increasing, and the difficulty of the HBM technology is also increasing.

### SUMMARY

The disclosure relates to the technical field of a three-dimensional preparing process, and in particular to a semiconductor package structure and a method for preparing a semiconductor package structure.

In view of the above, embodiments of the disclosure provide a semiconductor package structure and a method for preparing a semiconductor package structure.

A first aspect of an embodiment of the disclosure provides a semiconductor package structure. The semiconductor package structure includes:
a first substrate;
a first semiconductor die connected to the first substrate;
a second semiconductor die stack structure located on the first semiconductor die, the second semiconductor die stack structure including a plurality of second semiconductor dies sequentially stacked onto one another in a first direction, and a plurality of second conductive bumps being formed on a side of the second semiconductor die stack structure in the first direction, in which the first direction is a direction parallel to a plane where the first substrate is located; and
a second substrate, a signal line in the second substrate being connected to the plurality of second conductive bumps, and the second substrate being connected to the first substrate in a direction perpendicular to the plane where the first substrate is located.

A second aspect of an embodiment of the disclosure provides a method for preparing the semiconductor package structure according to any one of the above embodiments. The method includes the following operations.

A second semiconductor die stack structure is formed, the second semiconductor die stack structure including a plurality of second semiconductor dies sequentially stacked onto one another; and a plurality of second conductive bumps are formed on a side of the second semiconductor die stack structure in a stacking direction.

A first semiconductor die is formed.

A surface of the second semiconductor die stack structure perpendicular to the stacking direction is connected to a surface of the first semiconductor die.

A second substrate is provided, the second substrate being located, in the stacking direction, on the side of the second semiconductor die stack structure where the plurality of second conductive bumps are formed, and a signal line in the second substrate being connected to the plurality of second conductive bumps.

A first substrate is provided, the first semiconductor die is connected to the first substrate, and the second substrate is connected to the first substrate.

### BRIEF DESCRIPTION OF THE DRAWINGS

In order to more clearly illustrate the technical solution in the embodiments of the disclosure or in the related art, the drawings required to be used in the embodiments will be briefly described below. It will be apparent that the drawings described below are only some embodiments of the disclosure, and those skilled in the art may obtain other drawings according to these drawings without creative labor.

FIG. 1 is a schematic diagram of a semiconductor package structure according to an embodiment of the disclosure;

FIG. 2 is a schematic diagram of a semiconductor package structure according to another embodiment of the disclosure;

FIG. 3 is a side view of a plurality of second conductive bumps viewed in a first direction according to an embodiment of the disclosure;

FIG. 4A is a first schematic diagram of a semiconductor package structure according to yet another embodiment of the disclosure;

FIG. 4B is a second schematic diagram of a semiconductor package structure according to yet another embodiment of the disclosure;

FIG. 5 is a schematic flow diagram of a method for preparing a semiconductor package structure according to an embodiment of the disclosure; and

FIG. 6A is a first schematic diagram of a device of a semiconductor package structure during the preparation thereof according to an embodiment of the disclosure.

FIG. 6B is a second schematic diagram of a device of a semiconductor package structure during the preparation thereof according to an embodiment of the disclosure.

FIG. 6C is a third schematic diagram of a device of a semiconductor package structure during the preparation thereof according to an embodiment of the disclosure.

FIG. 6D is a fourth schematic diagram of a device of a semiconductor package structure during the preparation thereof according to an embodiment of the disclosure.

FIG. 6E is a fifth schematic diagram of a device of a semiconductor package structure during the preparation thereof according to an embodiment of the disclosure.

FIG. 6F is a sixth schematic diagram of a device of a semiconductor package structure during the preparation thereof according to an embodiment of the disclosure.

FIG. 6G is a seventh schematic diagram of a device of a semiconductor package structure during the preparation thereof according to an embodiment of the disclosure.

FIG. 6H is an eighth schematic diagram of a device of a semiconductor package structure during the preparation thereof according to an embodiment of the disclosure.

### LIST OF REFERENCE SYMBOLS

10—first substrate; 11—lead; 12—substrate connection bump; 101—groove;
20—first semiconductor die; 21—first conductive bump;
30—second semiconductor die stack structure; 300—second semiconductor die stack; 31—second semiconductor die; 311—through silicon via; 312—fourth conductive bump; 32—second conductive bump; 321—first sub-conductive bump; 322—second sub-conductive bump;
40—second substrate; 41—signal line; 411—ground line; 412—power supply line; 42—third conductive bump; 40′—remaining second substrate;
50—adhesive film;
60—dielectric layer;
70—filling layer;
80—packaging compound structure.

### DETAILED DESCRIPTION

Exemplary implementations disclosed in the disclosure are described in detail below with reference to the drawings. Although the drawings illustrate the exemplary implementations of the disclosure, it should be understood that the disclosure can be implemented in various forms, and should not be limited by the particular implementations described herein. On the contrary, the purpose of providing these implementations is to more thoroughly understand the disclosure, and to fully convey the scope disclosed in the disclosure to those skilled in the art.

In the following description, numerous specific details are provided for providing a more thorough understanding of the disclosure. However, it would be apparent to those skilled in the art that the disclosure can be implemented without one or more of these details. In other examples, in order to avoid confusion with the disclosure, some technical features known in the art are not described. That is, not all features of actual embodiments are described herein, and well-known functions and structures are not described in detail.

In the drawings, for clarity, the dimensions of layers, areas and elements and their relative dimensions may be exaggerated. Like reference symbols refer to like elements throughout the description.

It should be understood that when an element or layer is referred to as being “on”, “adjacent to”, “connected to” or “coupled to” other elements or layers, it can be directly on, adjacent to, connected to or coupled to the other elements or layers, or intervening elements or layers may be present. In contrast, when an element is referred to as being “directly on”, “directly adjacent to”, “directly connected to” or “directly coupled to” other elements or layers, intervening elements or layers are absent. It should be understood that although the terms first, second, third, etc., may be used to describe various elements, components, areas, layers and/or portions, those elements, components, areas, layers and/or portions may not be limited by these terms. The terms are merely used to distinguish one element, component, area, layer or portion from another element, component, area, layer or portion. Thus, a first element, component, area, layer or portion discussed below may be referred to as a second element, component, area, layer or portion without departing from the teachings of the disclosure. Moreover, when a second element, component, area, layer or portion is discussed, it does not mean that a first element, component, area, layer or portion is necessarily present in the disclosure.

Spatial relationship terms, such as “under”, “below”, “lower”, “beneath”, “above”, “upper”, etc., are used herein for ease of description to describe the relationship between one element or feature and another element or feature as illustrated in the drawings. It should be understood that the spatial relationship terms are intended to encompass different orientations of a device during the use and operation thereof, in addition to the orientation depicted in the drawings. For example, if the device in the drawings is turned over, an element or feature described as “below” or “beneath” or “under” another element or feature would be oriented “above” the another element or feature. Thus, the exemplary terms “below” and “under” can encompass both an orientation of above and below. The device may be additionally oriented (rotated by 90 degrees or at other orientations), and the spatial relationship terms used herein are interpreted accordingly.

The terms used herein are for the purpose of describing particular embodiments only, and are not intended to limit the disclosure. As used herein, the singular forms “a”, “an” and “said/the” are intended to include the plural forms as well, unless the context clearly indicates otherwise. It should be further understood that the terms “comprises” and/or “comprising”, when used in this specification, determine the presence of the features, integers, steps, operations, elements, and/or components, but do not exclude the presence or addition of one or more other features, integers, steps, operations, elements, components, and/or groups thereof. As used herein, the term “and/or” includes any and all combinations of one or more of the associated listed items.

For thoroughly understanding the disclosure, detailed operations and detailed structures will be set forth in the following description to illustrate technical solutions of the disclosure. Preferred embodiments of the disclosure are described as follows in detail. However, other implementations in addition to these detailed descriptions may also be included in the disclosure.

HBM technology is a main representative product of the development of DRAM from traditional 2D to 3D, which opens a way for a 3D DRAM. In HBM technology, dies are stacked onto one another by a through silicon via (TSV) technology, to increase throughput and overcome a limitation of a bandwidth in a single package. Several DRAM bare dies are stacked onto one another vertically, and the bare dies are connected to each other by the TSV technology. From a technical point of view, HBM makes full use of the space, and reduces the area, which is in line with a development trend of the miniaturization and integration of a semiconductor industry, and breaks through the bottleneck of the memory capacity and the bandwidth. Therefore, HBM is regarded as a solution of a new generation DRAM.

In the packaging of a 3D IC product, DRAM dies are generally stacked on a logic die in a parallel stack (P-Stack) manner. With the increasing requirement of an integration level of the HBM, the number of the stacked DRAM dies is increasing, and the difficulty of the HBM technology is also increasing. For example, a communication distance between the DRAM dies stacked onto one another at the high level and the logic die located at the bottom level is getting longer and longer. A communication delay between the DRAM dies located at one level and the logic die is different from a communication delay between the DRAM dies located at other levels different from the one level and the logic die, because a communication distance between the DRAM dies located at the one level and the logic die is different from a communication distance between the DRAM dies located at the other levels different from the one level and the logic die. The number of TSVs for communication is increased in a direct proportion, which leads to the sacrifice of an area of a wafer.

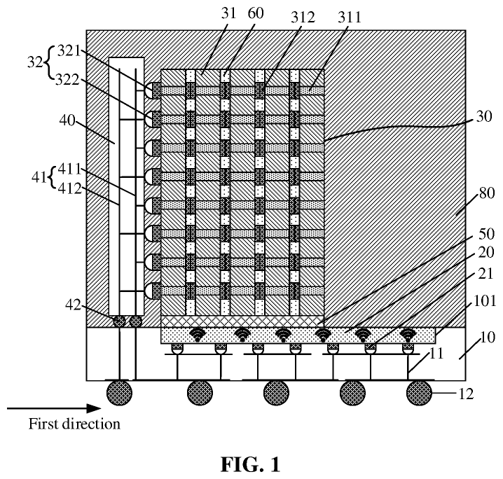

In view of the above, an embodiment of the disclosure provides a semiconductor package structure. FIG. 1 is a schematic diagram of a semiconductor package structure according to an embodiment of the disclosure.

Referring to FIG. 1, the semiconductor package structure includes:
a first substrate 10;
a first semiconductor die 20 connected to the first substrate 10;
a second semiconductor die stack structure 30 located on the first semiconductor die 20, where the second semiconductor die stack structure 30 includes a plurality of second semiconductor dies 31 sequentially stacked onto one another in a first direction, and a plurality of second conductive bumps 32 are formed on a side of the second semiconductor die stack structure 30 in the first direction, where the first direction is a direction parallel to a plane where the first substrate 10 is located; and
a second substrate 40, where a signal line 41 in the second substrate 40 is connected to the plurality of second conductive bumps 32, and the second substrate 40 is connected to the first substrate 10 in a direction perpendicular to the plane where the first substrate 10 is located.

In the embodiment of the disclosure, the plurality of second semiconductor dies of the second semiconductor die stack structure are stacked on the first semiconductor die in a side-by-side and a vertical stack (V-Stack) manner. In this way, the first semiconductor die may communicate with the plurality of second semiconductor dies in a wireless manner, which may effectively solve the difficulty of communication caused by the increase of the number of the plurality of second semiconductor dies when the plurality of second semiconductor dies are sequentially stacked on the first semiconductor die in a P-Stack manner. In addition, the first substrate supplies the electrical power to the first semiconductor die and the second semiconductor die stack structure in a wired manner, and exchanges signals with the first semiconductor die, which leads to a high reliability.

In an embodiment, the first substrate 10 may be a printed circuit board (PCB) or a redistributed substrate.

The first substrate 10 may include a first base (not shown), a first upper insulating dielectric layer (not shown) located on an upper surface of the first base, and a first lower insulating dielectric layer (not shown) located on a lower surface of the first base.

The first base may be a silicon substrate, a germanium substrate, a silicon germanium substrate, a silicon carbide substrate, a silicon on insulator (SOI) substrate or a germanium on insulator (GOI) substrate, etc. The first base may also be a substrate that includes other element semiconductors or compound semiconductors, such as a glass substrate or an III-V compound substrate (such as a gallium nitride substrate or a gallium arsenide substrate, etc.). The first base may also be a stack structure, such as Si/SiGe, etc., and may also be other epitaxial structures, such as germanium on insulator (SGOI), etc.

Each of the first upper insulating dielectric layer and the first lower insulating dielectric layer may be a solder resist layer. For example, the material of the first upper insulating dielectric layer and the material of the first lower insulating dielectric layer may be green paint.

Substrate connection bumps 12 are formed on a lower surface of the first substrate 10. The substrate connection bumps 12 may be configured to electrically connect the semiconductor package structure to an external device. The substrate connection bumps 12 may receive at least one of a control signal, a power signal, or a ground signal for operating the first semiconductor die and the plurality of second semiconductor dies from the external device, or may receive data signals to be stored in the first semiconductor die and the plurality of second semiconductor dies from the external device. The substrate connection bumps 12 may provide data in the first semiconductor die and the plurality of second semiconductor dies to the external device.

Each of the substrate connection bumps 12 includes a conductive material. In the embodiment of the disclosure, each of the substrate connection bumps 12 is a solder ball. It is to be understood that a shape of each of the substrate connection bumps according to the embodiment of the disclosure only serves as a lower level and feasible implementation in the embodiment of the disclosure, and does not constitute a limitation to the disclosure. Each of the substrate connection bumps may also be a structure with other shapes. The number, spacing and position of the substrate connection bumps are not limited to any particular arrangement, and various modifications may be made to the number, spacing and position of the substrate connection bumps.

In an embodiment, first conductive bumps 21 are formed on a surface of the first semiconductor die 20.

The material of the first conductive bumps 21 may include at least one of aluminum, copper, nickel, tungsten, platinum or gold.

The first semiconductor die 20 and the first substrate 10 are electrically connected to each other by the first conductive bumps 21. The first substrate 10 supplies the electrical power to the first semiconductor die in a wired manner, and exchanges signals with the first semiconductor die.

The first conductive bumps 21 are also connected to the substrate connection bumps 12 by leads 11 in the first substrate 10. In this way, the first semiconductor die 20 may exchange information with the external device by the substrate connection bumps 12.

In an embodiment, as shown in FIG. 1, a groove 101 is formed in the first substrate 10, and the first semiconductor die 20 is located in the groove 101. The first semiconductor die 20 is connected to the first substrate 10 by the first conductive bumps 21, and the second substrate 40 is connected to the first substrate 10 by third conductive bumps 42.

In this embodiment, the arrangement of the first semiconductor die in the groove of the first substrate may reduce a package height of the semiconductor package structure.

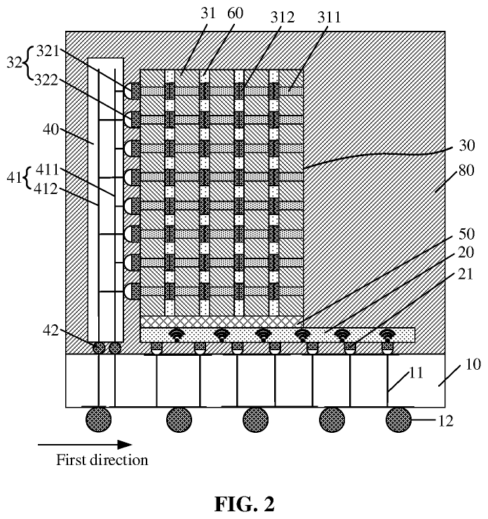

In another embodiment, as shown in FIG. 2, the first semiconductor die 20 is located above the first substrate 10. The first semiconductor die 20 is connected to the first substrate 10 by the first conductive bumps 21, and the second substrate 40 is connected to the first substrate 10 by third conductive bumps 42.

In this embodiment, the first semiconductor die is located above the first substrate. In this way, the first substrate dispenses with the groove, which leads to a simpler process. Furthermore, there is a gap between the first semiconductor die and the first substrate, which may increase the heat dissipation effect of the first semiconductor die.

The number of the plurality of second semiconductor dies 31 of the second semiconductor die stack structure 30 may be a plurality. In the embodiment of the disclosure, as shown in FIG. 1, the number of the plurality of second semiconductor dies 31 of the second semiconductor die stack structure 30 is five.

In an embodiment, the first semiconductor die 20 includes a logic die, and the second semiconductor die stack structure 30 includes DRAM dies.

In an embodiment, the semiconductor package structure further includes an adhesive film 50 located between the first semiconductor die 20 and the second semiconductor die stack structure 30.

The adhesive film 50 is configured to adhere the second semiconductor die stack structure 30 to the first semiconductor die 20, to enhance the adhesion between the second semiconductor die stack structure 30 and the first semiconductor die 20, which improves the firmness of the semiconductor package structure. In addition, the adhesion film may be configured to adjust a distance between the second semiconductor die stack structure and the first semiconductor die, to prevent an angular bonding of the second substrate and each of the plurality of second conductive bumps. However, the angular bonding of the second substrate and each of the plurality of second conductive bumps causes an additional stress, which may damage each of the plurality of second conductive bumps arranged on the second semiconductor die stack structure.

In an embodiment, the adhesive film 50 includes a die bonding film.

In an embodiment, the adhesive film includes a first adhesive film, and a second adhesive film (not shown) that is located on the first adhesive film. The elastic modulus of the second adhesive film is greater than the elastic modulus of the first adhesive film.

In the embodiment of the disclosure, since the first adhesive film is connected to the first semiconductor die, the first adhesive film mainly plays a role of bonding. The second adhesive film is connected to the second semiconductor die stack structure, and mainly plays a role of preventing the plurality of second semiconductor dies from warping. The elastic modulus of the second adhesive film is higher, which prevents the plurality of second semiconductor dies from warping in a packaging process. The elastic modulus of the first adhesive film is lower, which does not affect a bonding force between the first semiconductor die and the second semiconductor die stack structure in a subsequent process.

In an embodiment, the first semiconductor die 20 and the second semiconductor die stack structure 30 communicate with each other in a wireless manner. For example, a wireless coil (not shown) is arranged in each of DRAM dies of the second semiconductor die stack structure 30, and a wireless coil is arranged on the first semiconductor die 20 at a position thereof corresponding to the wireless coil arranged in each of the DRAM dies.

The first semiconductor die and the second semiconductor die stack structure communicate with each other in a wireless manner, which may effectively solve the difficulty of communication caused by the increase of the number of the plurality of second semiconductor dies, may reduce the number of TSVs and may reduce the difficulty of the process.

In an embodiment, as shown in FIG. 1, the semiconductor package structure further includes a plurality of through silicon vias 311 and a plurality of fourth conductive bumps 312. Each of the plurality of through silicon vias 311 penetrates through a respective one of the plurality of second semiconductor dies 31 in the first direction. The plurality of fourth conductive bumps 312 are located between any two adjacent second semiconductor dies 31 of the plurality of second semiconductor dies 31, and each of the plurality of fourth conductive bumps 312 is connected to a respective one of the plurality of through silicon vias 311. Each of the plurality of second conductive bumps 32 is connected to a respective one of the plurality of through silicon vias 311 and a respective one of the plurality of fourth conductive bumps 312.

In this embodiment, a power supply signal and a ground signal may be led to the plurality of second conductive bumps by the plurality of through silicon vias and the plurality of fourth conductive bumps.

The any two adjacent second semiconductor dies 31 of the second semiconductor die stack structure 30 are electrically connected to each other by a respective one of the plurality of through silicon vias and a respective one of the plurality of fourth conductive bumps.

The second semiconductor die stack structure is obtained in a hybrid bonding manner. In this way, the second semiconductor die stack structure may serve as a whole, to improve the mechanical strength of the second semiconductor die stack structure arranged vertically and reduce a pressure subjected by each of the plurality of second semiconductor dies.

The semiconductor package structure further includes a dielectric layer 60 located between any two adjacent second semiconductor dies 31 of the plurality of second semiconductor dies 31. The arrangement of the dielectric layer allows the any two adjacent second semiconductor dies to be insulated and isolated from one another. The arrangement of each of the plurality of fourth conductive bumps in the dielectric layer may reduce the possibility of coupling between fourth conductive bumps adjacent to each other of the plurality of fourth conductive bumps.

The material of the dielectric layer 60 includes an oxide. In a specific embodiment, the material of the dielectric layer 60 includes SiO2.

In addition, in order to improve the thickness of the second semiconductor die stack structure and in turn enhance the mechanical strength of the second semiconductor die stack structure, it is not necessary to perform a thinning treatment on an outermost die of the plurality of second semiconductor dies.

The material and structure of the second substrate 40 may be the same as the material and structure of the first substrate 10, and therefore will not be repeated herein.

In an embodiment, the signal line 41 includes a ground line 411 and a power supply line 412. The plurality of second conductive bumps 32 include a plurality of first sub-conductive bumps 321 and a plurality of second sub-conductive bump 322. The ground line 411 is electrically connected to each of the plurality of first sub-conductive bumps 321, and the power supply line 412 is electrically connected to each of the plurality of second sub-conductive bumps 322.

In this embodiment, a ground signal of the second semiconductor die stack structure 30 is led out to the ground line 411 by the plurality of first sub-conductive bumps 321, and a power supply signal of the second semiconductor die stack structure 30 is led out to the power supply line 412 by the plurality of second sub-conductive bumps 322. Then, the ground line 411 and the power supply line 412 are electrically connected to the first substrate 10 by the third conductive bumps 42. Therefore, the first substrate 10 supplies the electrical power to the second semiconductor die stack structure 30 by the third conductive bumps 42, the ground line 411 and the power supply line 412.

The third conductive bumps 42 are also connected to the substrate connection bumps 12 by the leads 11 in the first substrate 10. In this way, the second semiconductor die stack structure 30 may exchange information with the external device by the substrate connection bumps 12.

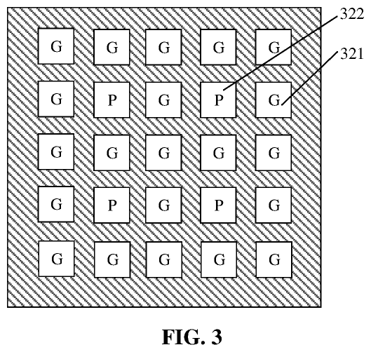

FIG. 3 is a side view of the plurality of second conductive bumps viewed in the first direction according to an embodiment of the disclosure.

As shown in FIG. 3, every two adjacent second sub-conductive bumps 322 of the plurality of second sub-conductive bumps 322 are separated from each other at least by a respective one of the plurality of first sub-conductive bumps 321 by which each of the plurality of second sub-conductive bumps 322 is surrounded.

In FIG. 3, each of powers (P) is the second sub-conductive bump 322, and each of grounds (G) is the first sub-conductive bump 321.

Each of the plurality of second sub-conductive bumps 322 is completely surrounded by first sub-conductive bumps 321, adjacent to said each of the plurality of second sub-conductive bumps 322, of the plurality of first sub-conductive bumps 321. Each of the plurality of first sub-conductive bumps 321 is connected to the ground signal, and each of the plurality of second sub-conductive bumps 322 is connected to the power supply signal. In this way, the crosstalk between different power supply signals may be reduced, and the shielding of the power supply may be enhanced.

In an embodiment, the semiconductor package structure further includes a packaging compound structure 80 located on the first substrate 10. The packaging compound structure 80 wraps at least the second semiconductor die stack structure 30 and the second substrate 40.

In the embodiment shown in FIG. 2, the packaging compound structure 80 also wraps the first semiconductor die 20.

The packaging compound structure 80 includes a silicon-containing compound. The silicon-containing compound may be a spin-on glass (SOG), a silicon-containing spin-on dielectric (SOD), or other silicon-containing spin-on materials.

The formation of the packaging compound structure 80 including a silicon-containing compound may reduce the problem of the warping of the second semiconductor die stack structure 30.

In an embodiment, the semiconductor package structure further includes a filling layer 70.

The filling layer 70 is located between the second semiconductor die stack structure 30 and the second substrate 40; and/or the filling layer 70 is located between the first substrate 10 and each of the first semiconductor die 20 and the second substrate 40.

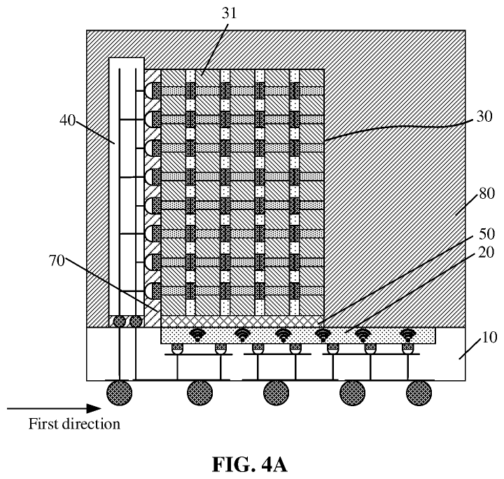

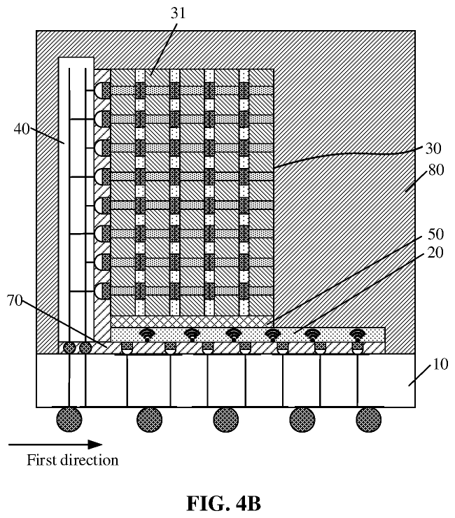

For example, in an embodiment, as shown in FIG. 4A, when the first semiconductor die 20 is located in the groove of the first substrate 10, the filling layer 70 may be located between the second semiconductor die stack structure 30 and the second substrate 40, and/or between the second substrate 40 and the first substrate 10.

In another embodiment, as shown in FIG. 4B, when the first semiconductor die 20 is located above the first substrate 10, the filling layer 70 may be located between the first substrate 10 and each of the first semiconductor die 20 and the second substrate 40, and/or between the second semiconductor die stack structure 30 and the second substrate 40.

Regarding the second semiconductor die stack structure stacked in three dimensions, the second semiconductor die stack structure has a high degree of warping because the thickness of the second semiconductor die stack structure in the first direction is small. When the second semiconductor die stack structure is vertically arranged on the first semiconductor die, it is difficult to weld the second semiconductor die stack structure to the second substrate because the second semiconductor die stack structure has a high degree of warping. Therefore, the filling layer is arranged between the second semiconductor die stack structure and the second substrate, and between the first substrate and the first semiconductor die, which may effectively reduce the impact caused by the mismatch between the overall temperature expansion property of the second semiconductor die stack structure and the overall temperature expansion property of the second substrate, and the mismatch between the overall temperature expansion property of the first semiconductor die and the overall temperature expansion property of the first substrate or by the external force, and may increase the reliability of the semiconductor package structure.

In an embodiment, the material of the filling layer 70 includes epoxy.

Epoxy may be coated on an edge of a die (the die is the first semiconductor die or the second semiconductor die stack structure) by means of the principle of the capillarity, to allow it to permeate into the die or a bottom of the substrate (the substrate is the first substrate or the second substrate), and then may be cured by heating it. The epoxy may effectively improve the mechanical strength of solder joints, and thus may improve the service life of the die.

In an embodiment, the Young's modulus of the filling layer 70 is greater than the Young's modulus of the packaging compound structure 80.

A Young's modulus is a physical quantity that may represent the ability of a solid material to resist a deformation. The Young's modulus is greater, the ability of the solid material to resist the deformation is greater. When the Young's modulus is too small, it is difficult to maintain the rigidity of the packaging compound structure, and it is easy to cause the problem such as the deformation, warping or damage of the packaging compound structure. Therefore, in the embodiment of the disclosure, the filling layer is formed, and the Young's modulus of the filling layer is greater than the Young's modulus of the packaging compound structure. In this way, the filling layer has a sufficient strength to support the whole packaging compound structure, so that it is not easy for the packaging compound structure to be deformed, warped or damaged.

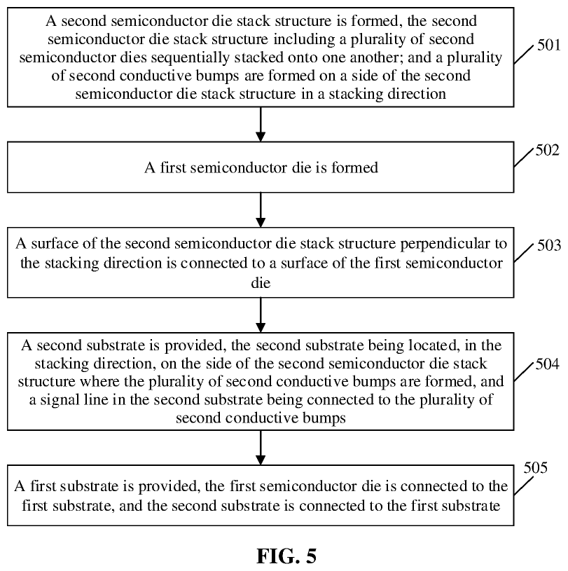

An embodiment of the disclosure also provides a method for preparing the semiconductor package structure according to any one of the above embodiments, as shown in FIG. 5. As shown in FIG. 5, the method includes the following operations.

At operation 501, a second semiconductor die stack structure is formed, the second semiconductor die stack structure including a plurality of second semiconductor dies sequentially stacked onto one another; and a plurality of second conductive bumps are formed on a side of the second semiconductor die stack structure in a stacking direction.

At operation 502, a first semiconductor die is formed.

At operation 503, a surface of the second semiconductor die stack structure perpendicular to the stacking direction is connected to a surface of the first semiconductor die.

At operation 504, a second substrate is provided, the second substrate being located, in the stacking direction, on the side of the second semiconductor die stack structure where the plurality of second conductive bumps are formed, and a signal line in the second substrate being connected to the plurality of second conductive bumps.

At operation 505, a first substrate is provided, the first semiconductor die is connected to the first substrate, and the second substrate is connected to the first substrate.

The method for preparing the semiconductor package structure according to the embodiment of the disclosure will be further described in detail below in combination with specific embodiments.

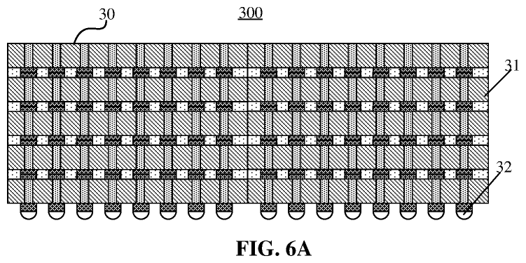

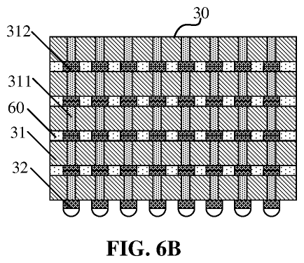

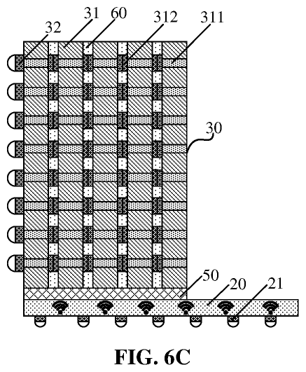

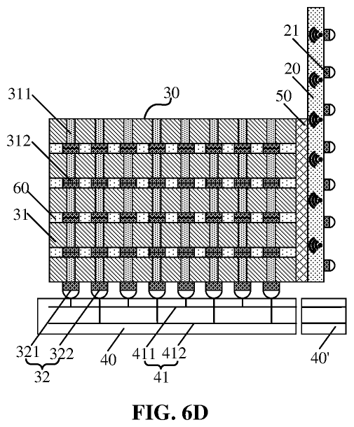

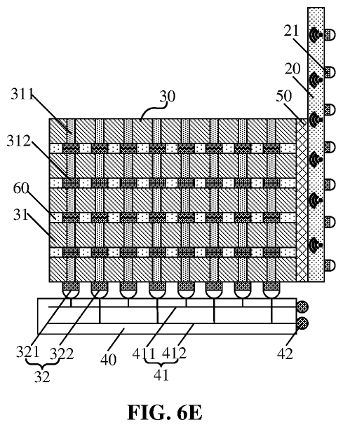

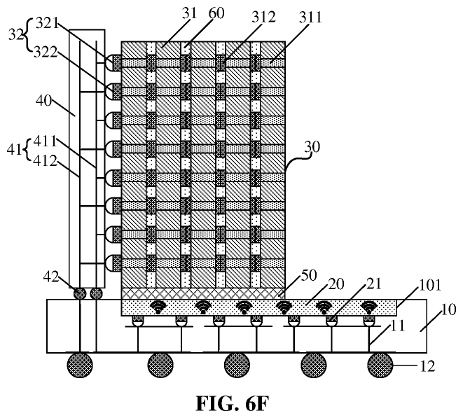

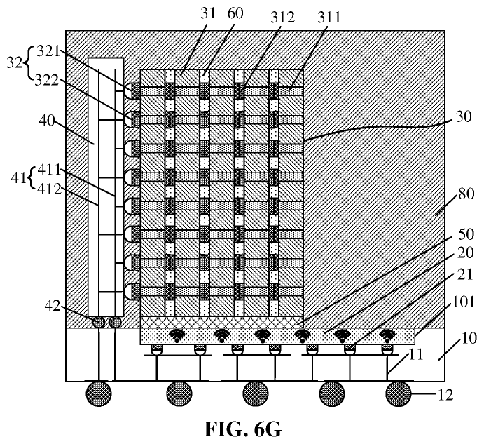

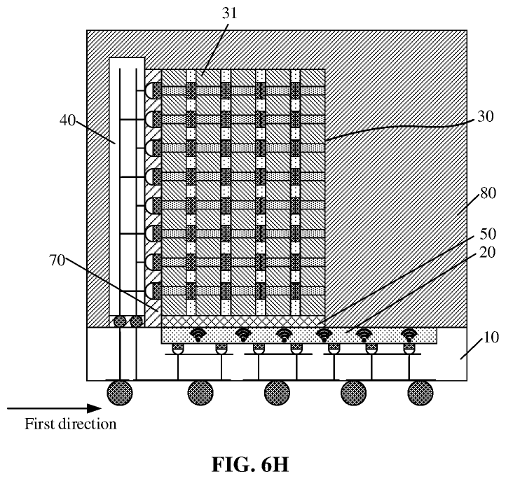

FIG. 6A to FIG. 6H are schematic diagrams of a device of a semiconductor package structure during the preparation thereof according to an embodiment of the disclosure.

First, referring to FIG. 6A and FIG. 6B, operation 501 is performed. At the operation 501, a second semiconductor die stack structure 30 is formed, the second semiconductor die stack structure 30 including a plurality of second semiconductor dies 31 sequentially stacked onto one another; and a plurality of second conductive bumps 32 are formed on a side of the second semiconductor die stack structure 30 in a stacking direction.

Referring to FIG. 6A, the formation of the second semiconductor die stack structure 30 includes the following operations. A plurality of through silicon vias 311 are formed in the stacking direction, each of the plurality of through silicon vias penetrating through a respective one of the plurality of second semiconductor dies 31.

A plurality of fourth conductive bumps 312 are formed between any two adjacent second semiconductor dies 31 of the plurality of second semiconductor dies 31, each of the plurality of fourth conductive bumps 312 being connected to a respective one of the plurality of through silicon vias 311.

The plurality of the second semiconductor dies 31 are connected to each other in a hybrid bonding manner to form a second semiconductor die stack 300.

The second semiconductor die stack 300 is formed into a plurality of second semiconductor die stack structures 30.

In practice, the second semiconductor die stack may be cut to form the plurality of second semiconductor die stack structures.

In an embodiment, each second semiconductor die stack structure 30 includes DRAM dies.

The number of the plurality of second semiconductor dies 31 of each second semiconductor die stack structure 30 may be a plurality. In the embodiment of the disclosure, as shown in FIG. 6B, the number of the plurality of second semiconductor dies 31 of each second semiconductor die stack structure 30 is five.

In an embodiment, as shown in FIG. 6A, the plurality of second conductive bumps 32 may be located on a respective one of the plurality of second semiconductor dies 31 at a bottom layer of the second semiconductor die stack 300. In other embodiments, the plurality of second conductive bumps 32 may also be located on a respective one of the plurality of second semiconductor dies 31 at a top layer of the second semiconductor die stack 300.

Referring to FIG. 6B, the method for preparing the semiconductor package structure further includes the following operation. A dielectric layer 60 is formed between any two adjacent second semiconductor dies 31 of the plurality of second semiconductor dies 31. The arrangement of the dielectric layer allows the any two adjacent second semiconductor dies to be insulated and isolated from one another. The arrangement of the plurality of fourth conductive bumps in the dielectric layer may reduce the possibility of coupling between fourth conductive bumps adjacent to each other of the plurality of fourth conductive bumps.

The material of the dielectric layer 60 includes an oxide. In a specific embodiment, the material of the dielectric layer 60 includes SiO2.

In addition, in order to improve the thickness of the second semiconductor die stack structure and in turn enhance the mechanical strength of the second semiconductor die stack structure, it is not necessary to perform a thinning treatment on an outermost die of the plurality of second semiconductor dies.

Next, referring to FIG. 6C, operation 502 and operation 503 are performed. At operation 502, a first semiconductor die 20 is formed. At operation 503, a surface of the second semiconductor die stack structure 30 perpendicular to the stacking direction is connected to a surface of the first semiconductor die 20.

In some embodiments, in a case that the stacking direction is a direction perpendicular to a plane where the first semiconductor die is located, the second semiconductor die stack structure is connected to the first semiconductor die after the second semiconductor die stack structure is rotated by 90 degrees.

In other embodiments, in a case that the stacking direction is a direction parallel to a plane where the first semiconductor die is located, there is no need to rotate the second semiconductor die stack structure.

In an embodiment, the first semiconductor die 20 includes a logic die.

In an embodiment, the method further includes the following operations. First conductive bumps 21 are formed on a surface of the first semiconductor die 20, and the second semiconductor die stack structure 30 is connected to a surface of the first semiconductor die 20 away from the first conductive bumps 21.

In an embodiment, an adhesive film 50 is formed on the first semiconductor die 20 after the first semiconductor die 20 is formed, and the second semiconductor die stack structure 30 is connected to the first semiconductor die 20 by the adhesive film 50.

The adhesive film 50 is configured to bond the second semiconductor die stack structure 30 to the first semiconductor die 20, to enhance the adhesion therebetween, which improves the firmness of the semiconductor package structure. In addition, the adhesion film may be configured to adjust a distance between the second semiconductor die stack structure and the first semiconductor die, to prevent an angular bonding of the second substrate and each of the plurality of second conductive bumps. However, the angular bonding of the second substrate and each of the plurality of second conductive bumps causes an additional stress, which may damage each of the plurality of second conductive bumps arranged on the second semiconductor die stack structure.

In an embodiment, the adhesive film 50 includes a die bonding film.

In an embodiment, the adhesive film includes a first adhesive film, and a second adhesive film (not shown) that is located on the first adhesive film. The elastic modulus of the second adhesive film is greater than the elastic modulus of the first adhesive film.

In the embodiment of the disclosure, since the first adhesive film is connected to the first semiconductor die, the first adhesive film mainly plays a role of bonding. The second adhesive film is connected to the second semiconductor die stack structure, and mainly plays a role of preventing each of the plurality of second semiconductor dies from warping. The elastic modulus of the second adhesive film is higher, which prevents each of the plurality of second semiconductor dies from warping in a packaging process. The elastic modulus of the first adhesive film is lower, which does not affect a bonding force between the first semiconductor die and the second semiconductor die stack structure in a subsequent process.

In an embodiment, the first semiconductor die 20 and the second semiconductor die stack structure 30 communicate with each other in a wireless manner. For example, a wireless coil (not shown) is arranged in each of DRAM dies of the second semiconductor die stack structure 30, and a wireless coil is arranged on the first semiconductor die 20 at a position thereof corresponding to the wireless coil arranged in each of the DRAM dies.

The first semiconductor die and the second semiconductor die stack structure communicate with each other in a wireless manner, which may effectively solve the difficulty of communication caused by the increase of the number of the plurality of second semiconductor dies.

Next, referring to FIG. 6D and FIG. 6E, operation 504 is performed. At operation 504, a second substrate 40 is provided, the second substrate 40 being located, in the stacking direction, on the side of the second semiconductor die stack structure 30 where the plurality of second conductive bumps 32 are formed, and a signal line 41 in the second substrate 40 being connected to the plurality of second conductive bumps 32.

Referring to FIG. 6D and FIG. 6E, the operation that the second substrate 40 is provided includes the following operations.

The second substrate 40 is cut, and third conductive bumps 42 are formed on the second substrate 40, where a surface of the second substrate 40 on which the third conductive bumps 42 are formed is flush with a surface of the second semiconductor die stack structure 30 close to the first semiconductor die 20.

Specifically, first, the second semiconductor die stack structure 30 is welded to the second substrate 40 by the plurality of second conductive bumps 32. Then, the second substrate 40 is cut to a suitable dimension, for example, is cut to be flush with the surface of the second semiconductor die stack structure 30 close to the first semiconductor die 20, and expose the signal line 41. Then, a remaining second substrate 40′ is removed.

It should be noted that, in the embodiment shown in FIG. 6D, the surface of the second substrate 40 on which the third conductive bumps 42 are formed is flush with the surface of the second semiconductor die stack structure 30 close to the first semiconductor die 20. In the embodiment in which the semiconductor package structure as shown in FIG. 2 is formed, the surface of the second substrate 40 on which the third conductive bumps 42 are formed is flush with a surface of the first semiconductor die 20 on which the first conductive bumps 21 are formed.

Next, referring to FIG. 6E, the third conductive bumps 42 are formed on a surface of the cut second substrate 40 which exposes the signal line 41, where each of the third conductive bumps 42 is connected to the signal line 41.

In an embodiment, the signal line 41 includes a ground line 411 and a power supply line 412. The plurality of second conductive bumps 32 include a plurality of first sub-conductive bumps 321 and a plurality of second sub-conductive bumps 322. The ground line 411 is electrically connected to each of the plurality of first sub-conductive bumps 321, and the power supply line 412 is electrically connected to each of the plurality of second sub-conductive bumps 322.

In this embodiment, a ground signal of the second semiconductor die stack structure 30 is led out to the ground line 411 by the plurality of first sub-conductive bumps 321, and a power supply signal of the second semiconductor die stack structure 30 is led out to the power supply line 412 by the plurality of second sub-conductive bumps 322. Then, the ground line 411 and the power supply line 412 are electrically connected to a subsequently formed first substrate 10 by the third conductive bumps 42. Therefore, the first substrate 10 supplies the electrical power to the second semiconductor die stack structure 30 by the third conductive bumps 42, the ground line 411 and the power supply line 412.

As shown in FIG. 3, every two adjacent second sub-conductive bumps 322 of the plurality of second sub-conductive bumps 322 are separated from each other at least by a respective one of the plurality of first sub-conductive bumps 321 by which each of the plurality of second sub-conductive bumps 322 is surrounded.

In FIG. 3, each of powers (P) is the second sub-conductive bump 322, and each of grounds (G) is the first sub-conductive bump 321.

Each of the plurality of second sub-conductive bumps 322 is completely surrounded by first sub-conductive bumps 321, adjacent to said each of the plurality of second sub-conductive bumps 322, of the plurality of first sub-conductive bumps 321. Each of the plurality of first sub-conductive bumps 321 is connected to the ground signal, and each of the plurality of second sub-conductive bumps 322 is connected to the power supply signal. In this way, the crosstalk between different power supply signals may be reduced, and the shielding of the power supply may be enhanced.

Next, referring to FIG. 6F, operation 505 is performed. At operation 505, a first substrate 10 is provided, the first semiconductor die 20 is connected to the first substrate 10, and the second substrate 40 is connected to the first substrate 10.

In an embodiment, the first substrate 10 may be a printed circuit board (PCB) or a redistributed substrate.

The first substrate 10 may include a first base (not shown), a first upper insulating dielectric layer (not shown) located on an upper surface of the first base, and a first lower insulating dielectric layer (not shown) located on a lower surface of the first base.

The first base may be a silicon substrate, a germanium substrate, a silicon germanium substrate, a silicon carbide substrate, a silicon on insulator (SOI) substrate or a germanium on insulator (GOI) substrate, etc. The first base may also be a substrate that includes other element semiconductors or compound semiconductors, such as a glass substrate or an III-V compound substrate (such as a gallium nitride substrate or a gallium arsenide substrate, etc.). The first base may also be a stack structure, such as Si/SiGe, etc., and may also be other epitaxial structures, such as germanium on insulator (SGOI), etc.

Each of the first upper insulating dielectric layer and the first lower insulating dielectric layer may be a solder resist layer. For example, the material of the first upper insulating dielectric layer and the material of the first lower insulating dielectric layer may be green paint.

Substrate connection bumps 12 are formed on a lower surface of the first substrate 10. The substrate connection bumps 12 may be configured to electrically connect the semiconductor package structure to an external device. The substrate connection bumps 12 may receive at least one of a control signal, a power signal, or a ground signal for operating the first semiconductor die and the plurality of second semiconductor dies from the external device, or may receive data signals to be stored in the first semiconductor die and the plurality of second semiconductor dies from the external device. The substrate connection bumps 12 may provide data in the first semiconductor die and the plurality of second semiconductor dies to the external device.

Each of the substrate connection bumps 12 includes a conductive material. In the embodiment of the disclosure, each of the substrate connection bumps 12 is a solder ball. It is to be understood that a shape of each of the substrate connection bumps according to the embodiment of the disclosure only serves as a lower level and feasible implementation in the embodiment of the disclosure, and does not constitute a limitation to the disclosure. Each of the substrate connection bumps may also be a structure with other shapes. The number, spacing and position of the substrate connection bumps are not limited to any particular arrangement, and various modifications may be made to the number, spacing and position of the substrate connection bumps.

In an embodiment, specifically, the first semiconductor die 20 is connected to the first substrate 10 by the first conductive bumps 21. The second substrate 40 is connected to the first substrate 10 by the third conductive bumps 42.

In an embodiment, as shown in FIG. 6F, a groove 101 is formed in the first substrate 10, and the first semiconductor die 20 is arranged in the groove 101.

In this embodiment, the arrangement of the first semiconductor die in the groove of the first substrate may reduce a package height of the semiconductor package structure.

In other embodiments, as shown in FIG. 2, the first semiconductor die 20 is located above the first substrate 10. The first conductive bumps 21 are located between the first semiconductor die 20 and the first substrate 10.

In this embodiment, the first semiconductor die is located above the first substrate. In this way, the first substrate dispenses with the groove, which leads to a simpler process. Furthermore, there is a gap between the first semiconductor die and the first substrate, which may increase the heat dissipation effect of the first semiconductor die.

The first semiconductor die 20 and the first substrate 10 are electrically connected to each other by the first conductive bumps 21. The first substrate 10 supplies the electrical power to the first semiconductor die in a wired manner, and exchanges signals with the first semiconductor die.

The first conductive bumps 21 are also connected to the substrate connection bumps 12 by leads 11 in the first substrate 10. In this way, the first semiconductor die 20 may exchange information with the external device by the substrate connection bumps 12.

The third conductive bumps 42 are also connected to the substrate connection bumps 12 by the leads 11 in the first substrate 10. In this way, the second semiconductor die stack structure 30 may exchange information with the external device by the substrate connection bumps 12.

Next, referring to FIG. 6G, the method further includes the following operation. A packaging compound structure 80 is formed on the first substrate 10, the packaging compound structure 80 wrapping at least the second semiconductor die stack structure 30 and the second substrate 40.

In the embodiment shown in FIG. 2, the packaging compound structure 80 also wraps the first semiconductor die 20.

The packaging compound structure 80 includes a silicon-containing compound. The silicon-containing compound may be a spin-on glass (SOG), a silicon-containing spin-on dielectric (SOD), or other silicon-containing spin-on materials.

The formation of the packaging compound structure 80 including a silicon-containing compound may reduce the problem of the warping of the second semiconductor die stack structure 30.

Next, the method further includes the following operation. A filling layer 70 is formed, the filling layer 70 being located between the second semiconductor die stack structure 30 and the second substrate 40; and/or the filling layer 70 being located between the first substrate 10 and each of the first semiconductor die 20 and the second substrate 40.

For example, in an embodiment, as shown in FIG. 6H, when the first semiconductor die 20 is located in the groove of the first substrate 10, the filling layer 70 may be located between the second semiconductor die stack structure 30 and the second substrate 40, and/or between the second substrate 40 and the first substrate 10.

In another embodiment, as shown in FIG. 4B, when the first semiconductor die 20 is located above the first substrate 10, the filling layer 70 may be located between the first substrate 10 and each of the first semiconductor die 20 and the second substrate 40, and/or between the second semiconductor die stack structure 30 and the second substrate 40.

Regarding the second semiconductor die stack structure stacked in three dimensions, the second semiconductor die stack structure has a high degree of warping because the thickness of the second semiconductor die stack structure in the first direction is small. When the second semiconductor die stack structure is vertically arranged on the first semiconductor die, it is difficult to weld the second semiconductor die stack structure to the second substrate because the second semiconductor die stack structure has a high degree of warping. Therefore, the filling layer is arranged between the second semiconductor die stack structure and the second substrate, and between the first substrate and the first semiconductor die, which may effectively reduce the impact caused by the mismatch between the overall temperature expansion property of the second semiconductor die stack structure and the overall temperature expansion property of the second substrate, and the mismatch between the overall temperature expansion property of the first semiconductor die and the overall temperature expansion property of the first substrate or by the external force, and may increase the reliability of the semiconductor package structure.

In an embodiment, the material of the filling layer 70 includes epoxy.

Epoxy may be coated on an edge of a die (the die is the first semiconductor die or the second semiconductor die stack structure) by means of the principle of the capillarity, to allow it to permeate into the die or a bottom of the substrate (the substrate is the first substrate or the second substrate), and then may be cured by heating it. The epoxy may effectively improve the mechanical strength of solder joints, and thus may improve the service life of the die.

In an embodiment, the Young's modulus of the filling layer 70 is greater than the Young's modulus of the packaging compound structure 80.

A Young's modulus is a physical quantity that may represent the ability of a solid material to resist a deformation. The Young's modulus is greater, the ability of the solid material to resist the deformation is greater. When the Young's modulus is too small, it is difficult to maintain the rigidity of the packaging compound structure, and it is easy to cause the problem such as the deformation, warping or damage of the packaging compound structure. Therefore, in the embodiment of the disclosure, the filling layer is formed, and the Young's modulus of the filling layer is greater than the Young's modulus of the packaging compound structure. In this way, the filling layer has a sufficient strength to support the whole packaging compound structure, so that it is not easy for the packaging compound structure to be deformed, warped or damaged.

What described above are merely preferred embodiments of the disclosure, and are not intended to limit the scope of protection of the disclosure. Any modification, equivalent replacement, improvement and the like made within the spirit and principle of the disclosure should be included in the scope of protection of the disclosure.

In an embodiment of the disclosure, a plurality of second semiconductor dies of a second semiconductor die stack structure are stacked on a first semiconductor die in a side-by-side and a V-Stack manner. In this way, the first semiconductor die may communicate with the plurality of second semiconductor dies in a wireless manner, which may effectively solve the difficulty of communication caused by the increase of the number of the plurality of second semiconductor dies when the plurality of second semiconductor dies are stacked on the first semiconductor die sequentially in a P-Stack manner. In addition, the first substrate supplies the electrical power to the first semiconductor die and the second semiconductor die stack structure in a wired manner, and exchanges signals with the first semiconductor die, which leads to a high reliability.

1. A semiconductor package structure, comprising:
a first substrate;
a first semiconductor die connected to the first substrate;
a second semiconductor die stack structure located on the first semiconductor die, the second semiconductor die stack structure including a plurality of second semiconductor dies sequentially stacked onto one another in a first direction, and a plurality of second conductive bumps being formed on a side of the second semiconductor die stack structure in the first direction, wherein the first direction is a direction parallel to a plane where the first substrate is located; and
a second substrate, a signal line in the second substrate being connected to the plurality of second conductive bumps, and the second substrate being connected to the first substrate in a direction perpendicular to the plane where the first substrate is located.

2. The semiconductor package structure according to claim 1, wherein
the first semiconductor die comprises a logic die, and the second semiconductor die stack structure comprises DRAM dies.

3. The semiconductor package structure according to claim 1, further comprising:
an adhesive film located between the first semiconductor die and the second semiconductor die stack structure.

4. The semiconductor package structure according to claim 3, wherein
the adhesive film comprises a first adhesive film, and a second adhesive film located on the first adhesive film, wherein an elastic modulus of the second adhesive film is greater than an elastic modulus of the first adhesive film.

5. The semiconductor package structure according to claim 1, wherein
the first semiconductor die and the second semiconductor die stack structure communicate with each other in a wireless manner.

6. The semiconductor package structure according to claim 1, wherein
a groove is formed in the first substrate, the first semiconductor die is located in the groove, the first semiconductor die is connected to the first substrate by first conductive bumps, and the second substrate is connected to the first substrate by third conductive bumps.

7. The semiconductor package structure according to claim 1, wherein
the first semiconductor die is located above the first substrate, the first semiconductor die is connected to the first substrate by first conductive bumps, and the second substrate is connected to the first substrate by third conductive bumps.

8. The semiconductor package structure according to claim 1, further comprising:
a plurality of through silicon vias, each of the plurality of through silicon vias penetrating through a respective one of the plurality of second semiconductor dies in the first direction; and
a plurality of fourth conductive bumps located between any two adjacent second semiconductor dies of the plurality of second semiconductor dies, each of the plurality of fourth conductive bumps being connected to a respective one of the plurality of through silicon vias,
wherein each of the plurality of second conductive bumps is connected to a respective one of the plurality of through silicon vias and a respective one of the plurality of fourth conductive bumps.

9. The semiconductor package structure according to claim 1, wherein
the signal line comprises a ground line and a power supply line, and the plurality of second conductive bumps comprise a plurality of first sub-conductive bumps and a plurality of second sub-conductive bumps; and
the ground line is electrically connected to each of the plurality of first sub-conductive bumps, and the power supply line is electrically connected to each of the plurality of second sub-conductive bumps.

10. The semiconductor package structure according to claim 9, wherein
every two adjacent second sub-conductive bumps of the plurality of second sub-conductive bumps are separated from each other at least by a respective one of the plurality of first sub-conductive bumps by which each of the plurality of second sub-conductive bumps is surrounded.

11. The semiconductor package structure according to claim 1, further comprising:
a filling layer, wherein the filling layer meets at least one of following requirements:
located between the second semiconductor die stack structure and the second substrate, or
located between the first substrate and each of the first semiconductor die and the second substrate.

12. The semiconductor package structure according to claim 11, further comprising:
a packaging compound structure located on the first substrate, the packaging compound structure wrapping at least the second semiconductor die stack structure and the second substrate,
wherein a Young's modulus of the filling layer is greater than a Young's modulus of the packaging compound structure.

13. A method for preparing the semiconductor package structure according to claim 1, comprising:
forming a second semiconductor die stack structure, the second semiconductor die stack structure including a plurality of second semiconductor dies sequentially stacked onto one another; and forming a plurality of second conductive bumps on a side of the second semiconductor die stack structure in a stacking direction;
forming a first semiconductor die;
connecting a surface of the second semiconductor die stack structure perpendicular to the stacking direction to a surface of the first semiconductor die;
providing a second substrate, the second substrate being located, in the stacking direction, on the side of the second semiconductor die stack structure where the plurality of second conductive bumps are formed, and a signal line in the second substrate being connected to the plurality of second conductive bumps; and
providing a first substrate, connecting the first semiconductor die to the first substrate, and connecting the second substrate to the first substrate.

14. The method according to claim 13, wherein
forming the second semiconductor die stack structure comprises:
forming a plurality of through silicon vias in the stacking direction, each of the through silicon vias penetrating through a respective one of the plurality of second semiconductor dies;
forming a plurality of fourth conductive bumps between any two adjacent second semiconductor dies of the plurality of second semiconductor dies, each of the plurality of fourth conductive bumps being connected to a respective one of the plurality of through silicon vias;
connecting the plurality of the second semiconductor dies to each other in a hybrid bonding manner to form a second semiconductor die stack; and
forming the second semiconductor die stack into a plurality of second semiconductor die stack structures.

15. The method according to claim 13, wherein
providing the second substrate comprises: cutting the second substrate, and forming third conductive bumps on the second substrate, wherein a surface of the second substrate on which the third conductive bumps are formed is flush with a surface of the second semiconductor die stack structure close to the first semiconductor die.

16. The method according to claim 13, wherein
forming a groove in the first substrate; and
arranging the first semiconductor die in the groove.

17. The method according to claim 13, further comprising:
forming an adhesive film on the first semiconductor die after the first semiconductor die is formed, wherein the second semiconductor die stack structure is connected to the first semiconductor die by the adhesive film.

18. The method according to claim 13, wherein
the first semiconductor die and the second semiconductor die stack structure communicate with each other in a wireless manner.

19. The method of claim 13, further comprising:
forming a filling layer, wherein the filling layer meets at least one of following requirements:
located between the second semiconductor die stack structure and the second substrate, or
located between the first substrate and each of the first semiconductor die and the second substrate.
